(19) United States
(12) Patent Application Publication
(10) Pub. No.: US 2026/0282608 A1
(43) Pub. Date: Sep. 17, 2026

(54) CHIP STRUCTURE AND PREPARATION METHOD THEREOF

(71) Applicant: SUZHOU LEKIN SEMICONDUCTOR CO., LTD., Suzhou (CN)

(72) Inventors: Fei GAO, Suzhou (CN); Yingnan HUANG, Suzhou (CN); Yanwei SHEN, Suzhou (CN)

(21) Appl. No.: 19/677,217

(22) Filed: May 14, 2026

Related U.S. Application Data
(63) Continuation of application No. PCT/CN2024/138665, filed on Dec. 12, 2024.

(30) Foreign Application Priority Data
Aug. 9, 2024 (CN) 202411090628.5

(51) Int. Cl. H10H 20/819; H10H 20/01

(52) U.S. Cl. CPC H10H 20/819; H10H 20/017; H10H 20/032

(57) ABSTRACT

The present disclosure relates to a chip structure and a preparation method thereof. The chip structure includes an epitaxial structure including a first doping type semiconductor layer, a second doping type semiconductor layer, and an active layer, and further includes a confinement layer. A material of the confinement layer is a semiconductor material composed of any one of Group III elements Ga, In, and Al, and any one of Group V elements N, As, and P. A space charge region is formed between the confinement layer and the second doping type semiconductor layer. In a case that the confinement layer has a second doping type, a doping concentration of the confinement layer is less than a doping concentration of the second doping type semiconductor layer in contact with the confinement layer, and in a case that the confinement layer contains Al, the Al content is less than 0.5%.

### RELATED APPLICATION

This application is a continuation application of International Application No. PCT/CN2024/138665, filed on Dec. 12, 2024, which claims priority to Chinese patent application No. 202411090628.5, filed on Aug. 9, 2024, entitled “CHIP STRUCTURE AND PREPARATION METHOD THEREOF,” the contents of which are incorporated herein by reference in their entirety.

### TECHNICAL FIELD

The present disclosure belongs to the field of semiconductor device technology, and in particular, to a Micro-LED chip structure and a preparation method thereof.

### BACKGROUND

Micro-LED display technology is a new display technology with advantages such as high brightness, high contrast, high resolution, energy conservation and environmental protection, long service life, and ease of implementation in flexible and transparent display.

For example, the size of a Micro-LED pixel is at the micrometer level, which can realize the self-luminous property, and thus the performance in the brightness is relatively high. This technology used in sunlight can maintain definition and cause the displayed content to be brighter and more vibrant.

For example, due to the self-luminous property, each pixel can be independently controlled to make black deeper and white brighter, thus achieving higher contrast. This technology can present a clearer and more realistic effect when a dynamic image or a high-definition video is viewed.

For example, the pixel density of the Micro-LED is very high, thus a very fine image display effect can be achieved. This technology provides a more delicate and richer visual effect when a high-definition movie is watched, a game is played, or an image is processed.

For example, compared to a traditional LCD display, the Micro-LED display has a significant advantage in power consumption and can achieve the effect of energy conservation and environmental protection. This technology can effectively reduce energy consumption and the impact on the environment during use.

For example, the Micro-LED has a long service life, which can exceed tens of thousands of hours. Due to the small size and the high reliability of the device of the Micro-LED, the durability of the Micro-LED is very high. During long-term use, this technology can maintain stable performance, thereby reducing the frequency of repair and replacement and the cost of maintenance.

For example, the Micro-LED may be prepared on a flexible substrate, thereby realizing flexible display. This technology has broad application prospects in future wearable devices, smart homes, and other fields. By preparing the Micro-LED on the flexible substrate, a bendable or a wearable display device can be realized, thereby bringing greater convenience and creativity to people's lives and work.

For example, the Micro-LED can realize transparent display. By preparing the Micro-LED on a transparent substrate, a display with high transparency may be realized, and a display effect of high definition can be maintained. This technology has broad application prospects in fields such as commercial display, home decoration, and in-vehicle navigation, thereby providing people with a more intuitive and realistic visual experience.

However, as the size of the Micro-LED shrinks, the external quantum efficiency at low current density decreases sharply, which is mainly due to a non-radiative recombination center and leakage current introduced by the sidewall damage caused by plasma etching during the manufacturing process.

In the prior art, improvement can be made in the following manner: for example, sidewalls of a light-emitting structure are passivated to reduce the non-radiative recombination center and leakage current introduced by the sidewall damage. However, the improvement made in this manner is far from sufficient to meet the requirement. Although some optimization effects can be produced, the effect of side length becomes more obvious as the device gets smaller. For another example, an electrode is disposed at a position away from the sidewall. However, the space of the device is limited, and current expansion occurs, therefore, the actual effect after the improvement is not good. For yet another example, isolation can be achieved in an ion implantation manner, however, the ion implantation itself may introduce many defects, and the defects may bring the non-radiative recombination center. Meanwhile, eliminating the ion implantation requires high temperature, and the high temperature causes a significant challenge to the device integration.

The information disclosed in the background is merely intended to enhance the understanding of the general background of the present disclosure and should not be regarded as acknowledging or implying that the information constitutes prior art known to those of ordinary skill in the art.

### SUMMARY

An objective of the present disclosure is to provide a Micro-LED chip structure and a preparation method thereof, which can solve the problems in the prior art.

To achieve the above objective, a specific embodiment of the present disclosure provides a chip structure, including:
an epitaxial structure, the epitaxial structure including a first doping type semiconductor layer, a second doping type semiconductor layer, and an active layer disposed between the first doping type semiconductor layer and the second doping type semiconductor layer, where a mesa structure is formed on a side of the second doping type semiconductor layer facing away from the active layer,
where the epitaxial structure further includes a confinement layer, the confinement layer is formed on a side surface of the mesa structure and is in contact with the mesa structure, and the confinement layer has a second doping type, a first doping type, or no doping type,
where a material of the confinement layer is a semiconductor material composed of any one of Group III elements Ga, In, and Al, and any one of Group V elements N, As, and P,
where a space charge region is formed between the confinement layer and the second doping type semiconductor layer, and the space charge region controls a current flow path to allow current to bypass the side surface of the mesa structure, and
where in a case that the confinement layer has the second doping type, a doping concentration of the confinement layer is less than a doping concentration of the second doping type semiconductor layer in contact with the confinement layer, and in a case that the confinement layer contains Al, the Al content is less than 0.5%.

In one or more embodiments of the present disclosure, the second doping type semiconductor layer includes a second doping type electron blocking layer formed on a surface of the active layer and a second doping type cap layer formed on a surface of the second doping type electron blocking layer, a doping concentration of the second doping type electron blocking layer is 1E18 to 1E20, and a doping concentration of the second doping type cap layer is 1E19 to 1E21.

In one or more embodiments of the present disclosure, the mesa structure is formed by partially etching the second doping type cap layer in a thickness direction, where in the case that the confinement layer has the second doping type, the doping concentration of the confinement layer is less than the doping concentration of the second doping type cap layer.

In one or more embodiments of the present disclosure, a height of the mesa structure is less than a thickness of the second doping type cap layer, and the height of the mesa structure is greater than half the thickness of the second doping type cap layer.

In one or more embodiments of the present disclosure, the mesa structure is formed by completely etching the second doping type cap layer in a thickness direction, the height of the mesa structure is equal to a thickness of the second doping type cap layer, and in the case that the confinement layer has the second doping type, the doping concentration of the confinement layer is less than the doping concentration of the second doping type cap layer and less than the doping concentration of the second doping type electron blocking layer.

In one or more embodiments of the present disclosure, the confinement layer is formed in an etched region, and a thickness of the confinement layer is equal to the height of the mesa structure.

In one or more embodiments of the present disclosure, in a case that the confinement layer has the first doping type, the doping concentration of the confinement layer ranges from 1E17 to 5E19, and in the case that the confinement layer has the second doping type, the doping concentration of the confinement layer ranges from 1E17 to 1E20.

In one or more embodiments of the present disclosure, the chip structure further includes:
a first electrode electrically connected to the first doping type semiconductor layer, and
a second electrode electrically connected to the second doping type semiconductor layer.

In one or more embodiments of the present disclosure, the second electrode is formed on a surface of the mesa structure, and the second electrode is electrically isolated from the confinement layer via an insulation layer.

In one or more embodiments of the present disclosure, the first electrode is formed on a surface of the first doping type semiconductor layer facing away from the active layer, and an orthographic projection of the first electrode in a thickness direction overlaps with an orthographic projection of the mesa structure in the thickness direction; or
the first electrode is formed on a side surface of the first doping type semiconductor layer.

A specific embodiment of the present disclosure provides a preparation method of a chip structure, the method including:
providing a substrate, and sequentially forming a first doping type semiconductor layer, an active layer, and a second doping type semiconductor layer on the substrate;
etching the second doping type semiconductor layer in a thickness direction to form a mesa structure;
growing a confinement layer in an etched region, where the confinement layer is in contact with the mesa structure, the confinement layer has a second doping type, a first doping type, or no doping type, and in a case that the confinement layer has the second doping type, a doping concentration of the confinement layer is less than a doping concentration of the second doping type semiconductor layer in contact with the confinement layer; and
forming a first electrode electrically connected to the first doping type semiconductor layer and a second electrode electrically connected to the second doping type semiconductor layer.

Compared to the prior art, in the chip structure and the preparation method thereof provided in the embodiments of the present disclosure, by forming the confinement layer with a different doping type or a different concentration from that of the second doping type semiconductor layer in the etched region of the second doping type semiconductor layer, the space charge region is formed between the confinement layer and the etched sidewalls, so as to control the current flow path to allow the current to bypass the etched sidewalls, thereby reducing a non-radiative recombination center and leakage current introduced by etching damage, while also avoiding introducing other problems that are adversely affect the device performance.

In the chip structure and the preparation method thereof provided in the embodiments of the present disclosure, by controlling the concentration difference between the confinement layer and the second doping type semiconductor layer and a proportion of the confinement layer relative to the thickness of the second doping type semiconductor layer, a size of the space charge region formed between the confinement layer and the second doping type semiconductor layer is controlled, the current-limiting effect of the space charge region on the current is improved, thereby avoiding phenomena of the non-radiative recombination center and the leakage current of the etched sidewalls.

### BRIEF DESCRIPTION OF THE DRAWINGS

To describe the technical solution in the embodiments of the present disclosure or in the prior art more clearly, the following briefly describes the accompanying drawings required for describing the embodiments or the prior art. Obviously, the accompanying drawings in the following description merely show some embodiments of the present disclosure, and those of ordinary skill in the art may still derive other drawings from these accompanying drawings without creative efforts.

FIG. 1 is a cross-sectional view of a chip structure in the first, third, fifth, seventh, ninth, and twelfth embodiments of the present disclosure;

FIG. 2 is a cross-sectional view of a chip structure in the second, fourth, sixth, eighth, and tenth embodiments of the present disclosure;

FIG. 3 is a cross-sectional view of a chip structure in the eleventh embodiment of the present disclosure; and

FIG. 4 is a process flowchart of a preparation method of a chip structure according to an embodiment of the present disclosure.

### DETAILED DESCRIPTION

To enable those skilled in the art to better understand the technical solution of the present disclosure, the following clearly and fully describes the technical solutions in the embodiments of the present disclosure with reference to the accompanying drawings in the embodiments of the present disclosure. Obviously, the described embodiments are merely some rather than all the embodiments of the present disclosure. Based on the embodiments of the present disclosure, all other embodiments obtained by those of ordinary skill in the art without creative efforts shall fall within the protection scope of the present disclosure.

As described in the background, the Micro-LED display technology is a new display technology, which has advantages such as high brightness, high contrast, high resolution, energy conservation and environmental protection, long service life, and ease of implementation in the flexible and transparent display. However, with the decrease in the size of the Micro-LED, the external quantum efficiency at a low current density decreases sharply, which is mainly due to the introduction of a non-radiative recombination center and leakage current caused by sidewall damage introduced by plasma etching during the manufacturing process.

In the prior art, improvement can be made in the following manner: for example, processing the passivation on a sidewall of a light-emitting structure to reduce the non-radiative recombination center and leakage current introduced by the sidewall damage. However, the improvement made in this manner is far from sufficient to meet the requirement. Although some optimization effects can be generated, the effect of side length becomes more obvious as the device gets smaller. For another example, an electrode is disposed at a position away from the sidewall. However, the space of the device is limited, and current expansion occurs, therefore, the actual effect after the improvement is not good. For yet another example, the isolation can be achieved in an ion implantation manner, however, the ion implantation itself may introduce many defects, which in turn create the nonradiative recombination center. Meanwhile, eliminating the ion implantation requires a high temperature, and the high temperature causes a significant challenge to the device integration.

To solve the above technical problems, the present disclosure provides a chip structure and a preparation method thereof, which are suitable for the Micro-LED.

The chip structure provided in the embodiments of the present disclosure at least includes an epitaxial structure. The epitaxial structure at least includes a first doping type semiconductor layer, an active layer, and a second doping type semiconductor layer, which are disposed in sequence. A mesa structure is formed by partially etching the second doping type semiconductor layer in a thickness direction.

The first doping type semiconductor layer may be formed by doping a first conductive type semiconductor layer with a first dopant. A material of the first conductive type semiconductor layer is a semiconductor material of Alₓ₁In_{y1}Ga_{(1-x1-y1)}N (0≤x₁≤1, 0≤y₁≤1, 0≤x₁+y₁≤1), which may be formed from any one or more of GaN, GaNAs, InP, InAlGaN, AlGaAs, GaP, GaAs, GaAsP, and AlGaInP, which is not limited herein. A material of the first dopant includes an N-type dopant such as Si, Ge, Sn, Se, Te, etc.

The second doping type semiconductor layer may be formed by doping a second conductive type semiconductor layer with a second dopant, where a material of the second conductive type semiconductor layer is a semiconductor material of Alₓ₂In_{y2}Ga_{1-x2-y2}N (0≤x₂≤1, 0≤y₂≤1, 0≤x₂+y₂≤1), which may be formed from any one or more of GaN, GaNAs, InP, AlInN, AlGaAs, GaP, GaAs, GaAsP, and AlGaInP, which is not limited herein. A material of the second dopant includes a P-type dopant such as Mg, Zn, Ca, Sr, Ba, etc.

The mesa structure formed by partially etching the second doping type semiconductor layer in the thickness direction has a specific width ranging from 1 μm to 30 μm, specifically, such as 1.5 μm, 3 μm, 6 μm, 8 μm, 10 μm, 15 μm, or 20 μm, and an optional width range may be 1 μm to 20 μm, 1 μm to 10 μm, and 3 μm to 8 μm, etc. When the mesa structure has a relatively narrow width, it has a function of increasing the current density within the semiconductor device and confining the current within the semiconductor device.

The epitaxial structure further includes a confinement layer, which is formed on a side surface of the mesa structure and entirely disposed in an etched region of the second doping type semiconductor layer. The confinement layer, the mesa structure, and the second doping type semiconductor layer are in contact with each other. The confinement layer is configured to have a second doping type, a first doping type, or no doping type. In a case that the confinement layer has the second doping type, a doping concentration of the confinement layer is less than a doping concentration of the second doping type semiconductor layer in contact with the confinement layer.

A material of the confinement layer is a semiconductor material, and a lattice of the confinement layer matches a lattice of the second doping type semiconductor layer. The material of the confinement layer is composed of any one of Group III elements Ga, In, and Al, and any one of Group V elements N, As, and P. Optionally, the material of the confinement layer includes GaN, GaAs, GaNAs, InGaN, AlGaN, AlInGaN, etc. If the confinement layer contains element Al, the element Al content is less than 0.5%. The limitation of the Al content is to match the lattice and improve doping efficiency during the growth of the confinement layer. Based on this, a space charge region is formed between the confinement layer and the second doping type semiconductor layer. An electric field in the space charge region can prevent the diffusion of free electrons and holes toward a side surface of the mesa structure, which prevents the flow of the current, so as to control the current flow path to allow the current to bypass the side surfaces (etched sidewalls) of the mesa structure, thus significantly reducing a non-radiative recombination center and leakage current introduced by the etching damage.

In an optional embodiment, the second doping type semiconductor layer includes a second doping type electron blocking layer formed on a surface of the active layer and a second doping type cap layer formed on a surface of the second doping type electron blocking layer. A doping concentration of the second doping type electron blocking layer is 1E18 to 1E20, and a thickness of the second doping type electron blocking layer is 10 nm to 100 nm. A doping concentration of the second doping type cap layer is 1E19 to 1E21, and a thickness of the second doping type cap layer is 10 nm to 500 nm.

The mesa structure is formed by partially etching the second doping type cap layer in the thickness direction. In this embodiment, the second doping type semiconductor layer in contact with the confinement layer is merely the second doping type cap layer. Therefore, in the case that the confinement layer has the second doping type, the doping concentration of the confinement layer is less than the doping concentration of the second doping type cap layer.

A height of the mesa structure is less than a thickness of the second doping type cap layer, and the height of the mesa structure is greater than half the thickness of the second doping type cap layer. That is, the thickness of the confinement layer grown in the etched region of the second doping type cap layer needs to be greater than half the thickness of the second doping type cap layer. Optionally, the thickness of the confinement layer is greater than ⅔ or ¾ of the thickness of the second doping type cap layer. A remaining thickness of the second doping type cap layer after being etched is as small as possible, while the difference between the doping concentration of the grown confinement layer and the doping concentration of the second doping type cap layer is as large as possible, so that the space charge region formed between them is much larger than the remaining thickness of the second doping type cap layer after being etched to obtain the maximum current-limiting effect, thereby minimizing the non-radiative recombination center and leakage current introduced by the etching damage.

In another optional embodiment, the second doping type semiconductor layer includes the second doping type electron blocking layer formed on the surface of the active layer, and the second doping type cap layer formed on the surface of the second doping type electron blocking layer. The doping concentration of the second doping type electron blocking layer is 1E18 to 1E20, and the thickness of the second doping type electron blocking layer is 10 nm to 100 nm. The doping concentration of the second doping type cap layer is 1E19 to 1E21, and the thickness of the second doping type cap layer is 10 nm to 500 nm.

The mesa structure is formed by completely etching the second doping type cap layer in the thickness direction. In the embodiment, the second doping type semiconductor layer in contact with the confinement layer is the second doping type cap layer and the second doping type electron blocking layer. Therefore, in the case that the confinement layer has the second doping type, the doping concentration of the confinement layer is less than the doping concentration of the second doping type cap layer and is less than the doping concentration of the second doping type electron blocking layer.

The height of the mesa structure is equal to the thickness of the second doping type cap layer. That is, a thickness of the confinement layer grown in an etched region of the second doping type cap layer is equal to the thickness of the second doping type cap layer. Optionally, the difference between the doping concentration of the grown confinement layer and the doping concentration of the second doping type cap layer is as large as possible, so that the space charge region with a relatively large thickness is formed between them to obtain the maximum current-limiting effect, thereby minimizing the non-radiative recombination center and leakage current introduced by the etching damage.

It could be understood that the epitaxial structure in the present disclosure is not limited to the structure described above, but may also include other layer structures, such as a substrate, a buffer layer, etc. The invention point of the present disclosure lies in the second doping type semiconductor layer and the grown confinement layer, and therefore the chip structure that includes the second doping type semiconductor layer, the growth confinement layer, and the limitation relationship between them as described in the present disclosure should all fall within the scope of protection of the present disclosure.

The chip structure of the present disclosure also includes a first electrode and a second electrode.

The first electrode is electrically connected to the first doping type semiconductor layer. Optionally, the first electrode is formed on a surface of the first doping type semiconductor layer facing away from the active layer, and an orthographic projection of the first electrode in the thickness direction overlaps with an orthographic projection of the mesa structure in the thickness direction. Or, the first electrode is formed on a side surface of the first doping type semiconductor layer.

The second electrode is electrically connected to the second doping type semiconductor layer. Optionally, the second electrode is formed on the surface of the mesa structure, and isolated from the confinement layer via an insulation layer.

In the chip structure provided in the embodiments of the present disclosure, firstly, by forming the confinement layer with a different doping type or a different concentration from that of the second doping type semiconductor layer in the etched region of the second doping type semiconductor layer, the space charge region is formed between the etched sidewalls, and the electric field in the space charge region prevents the further diffusion of free electrons and holes. Due to the lack of free carriers (electrons and holes) in the space charge region, it forms an insulation region that prevents the flow of the current, so that the current flow path is controlled to allow the current to bypass the etched sidewalls, thereby significantly reducing the non-radiative recombination center and leakage current introduced by the etching damage, while also avoiding introducing other problems that are adversely affect the device performance. Secondly, by controlling the concentration difference between the confinement layer and the second doping type semiconductor layer in contact with the confinement layer and controlling a proportion of the confinement layer relative to the thickness of the second doping type semiconductor layer, a size of the space charge region formed between them is controlled, and the current-limiting effect of the space charge region on the current is further improved, thereby avoiding phenomena of the non-radiative recombination center and the leakage current of the etched sidewalls.

The chip structure of the present disclosure will be described in detail below through several specific embodiments with reference to the accompanying drawings to facilitate a clearer understanding of the technical solutions of the present disclosure.

### First Embodiment

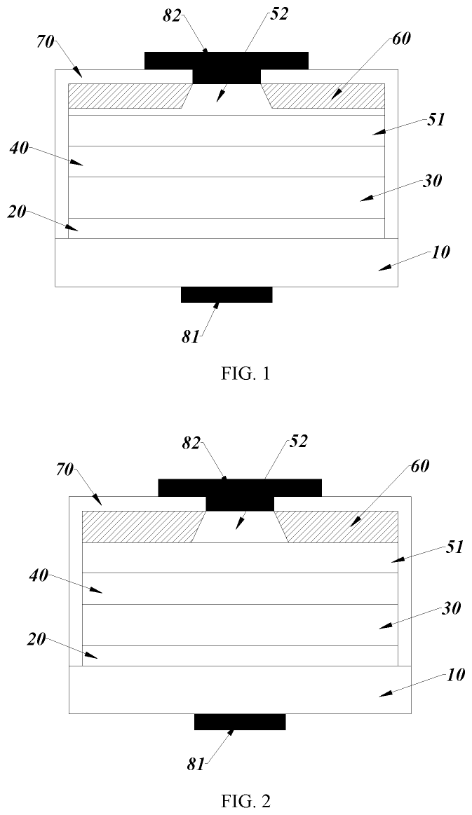

As shown in FIG. 1, a chip structure in the first embodiment includes, in sequence from bottom to top, a substrate 10, a buffer layer 20, an N-type layer 30, an active layer 40, a P-type EBL layer (electron blocking layer) 51, and a P-type cap layer 52. The P-type cap layer 52 is partially etched in a thickness direction to form a mesa structure. A confinement layer 60 is disposed on a side surface of the mesa structure (in the etched region of the P-type cap layer 52).

A material of the P-type EBL layer 51 is P-type AlGaN. A doping concentration of the P-type EBL layer 51 is 1E18. A thickness of the P-type EBL layer 51 is 50 nm.

A material of the P-type cap layer 52 is P-type GaN. A doping concentration of the P-type cap layer 52 is 1E19. A thickness of the P-type cap layer 52 is 50 nm. A height of the mesa structure is 30 nm, and a width of the mesa structure is 3 μm.

A material of the confinement layer 60 is GaN. A doping type of the confinement layer 60 is P-type. A doping concentration of the confinement layer 60 is 1E18. A thickness of the confinement layer 60 is 30 nm.

The chip structure also includes an insulation layer 70, which is formed on a side surface of an epitaxial structure composed of the buffer layer 20, the N-type layer 30, the active layer 40, the P-type EBL layer (electron blocking layer) 51 and the confinement layer 60 and on an upper surface (a surface facing away from the substrate 10) of the confinement layer 60. A first electrode 81 is disposed on a lower surface (a surface facing away from the buffer layer 20) of the substrate 10, and overlaps with an orthographic projection of the mesa structure in the thickness direction. The second electrode 82 is disposed on an upper surface of the P-type cap layer 52.

### Second Embodiment

As shown in FIG. 2, a chip structure in the second embodiment includes, in sequence from bottom to top, includes a substrate 10, a buffer layer 20, an N-type layer 30, an active layer 40, a P-type EBL layer (electron blocking layer) 51, and a P-type cap layer 52. The P-type cap layer 52 is completely etched in a thickness direction to form a mesa structure. A confinement layer 60 is disposed on a side surface of the mesa structure (in an etched region of the P-type cap layer 52).

A material of the P-type EBL layer 51 is P-type AlGaN. A doping concentration of the P-type EBL layer 51 is 1E18. A thickness of the P-type EBL layer 51 is 50 nm.

A material of the P-type cap layer 52 is P-type GaN. A doping concentration of the P-type cap layer 52 is 1E19. A thickness of the P-type cap layer 52 is 50 nm. A height of the mesa structure is 50 nm, and a width of the mesa structure is 3 μm.

A material of the confinement layer 60 is GaN. A doping type of the confinement layer 60 is P-type. A doping concentration of the confinement layer 60 is 1E17. A thickness of the confinement layer 60 is 50 nm.

The chip structure also includes an insulation layer 70, which is formed on a side surface of an epitaxial structure composed of the buffer layer 20, the N-type layer 30, the active layer 40, the P-type EBL layer (electron blocking layer) 51 and the confinement layer 60 and on an upper surface (a surface facing away from the substrate 10) of the confinement layer 60. A first electrode 81 is disposed on a lower surface (a surface facing away from the buffer layer 20) of the substrate 10, and overlaps with an orthographic projection of the mesa structure in the thickness direction. The second electrode 82 is disposed on an upper surface of the P-type cap layer 52.

### Third Embodiment

As shown in FIG. 1, a chip structure in the third embodiment includes, in sequence from bottom to top, a substrate 10, a buffer layer 20, an N-type layer 30, an active layer 40, a P-type EBL layer (electron blocking layer) 51, and a P-type cap layer 52. The P-type cap layer 52 is partially etched in a thickness direction to form a mesa structure. A confinement layer 60 is disposed on a side surface of the mesa structure (in an etched region of the P-type cap layer 52).

A material of the P-type EBL layer 51 is P-type AlGaN. A doping concentration of the P-type EBL layer 51 is 1E19. A thickness of the P-type EBL layer 51 is 50 nm.

A material of the P-type cap layer 52 is P-type GaN. A doping concentration of the P-type cap layer 52 is 3E19. A thickness of the P-type cap layer 52 is 100 nm. A height of the mesa structure is 80 nm, and a width of the mesa structure is 8 μm.

A material of the confinement layer 60 is GaN. A doping type is P-type. A doping concentration of the confinement layer 60 is 1E19. A thickness of the confinement layer 60 is 80 nm.

The chip structure also includes an insulation layer 70, which is formed on a side surface of an epitaxial structure composed of the buffer layer 20, the N-type layer 30, the active layer 40, the P-type EBL layer (electron blocking layer) 51 and the confinement layer 60 and on an upper surface (a surface facing away from the substrate 10) of the confinement layer 60. A first electrode 81 is disposed on a lower surface (a surface facing away from the buffer layer 20) of the substrate 10, and overlaps with an orthographic projection of the mesa structure in the thickness direction. The second electrode 82 is disposed on an upper surface of the P-type cap layer 52.

### Fourth Embodiment

As shown in FIG. 2, a chip structure in the fourth embodiment includes, in sequence from bottom to top, a substrate 10, a buffer layer 20, an N-type layer 30, an active layer 40, a P-type EBL layer (electron blocking layer) 51, and a P-type cap layer 52. The P-type cap layer 52 is completely etched in a thickness direction to form a mesa structure. A confinement layer 60 is disposed on a side surface of the mesa structure (in an etched region of the P-type cap layer 52).

A material of the P-type EBL layer 51 is P-type AlGaN. A doping concentration of the P-type EBL layer 51 is 1E19. A thickness of the P-type EBL layer 51 is 50 nm.

A material of the P-type cap layer 52 is P-type GaN. A doping concentration of the P-type cap layer 52 is 3E19. A thickness of the P-type cap layer 52 is 100 nm. A height of the mesa structure is 100 nm, and a width of the mesa structure is 8 μm.

A material of the confinement layer 60 is GaN. A doping type is P-type. A doping concentration of the confinement layer 60 is 1E18. A thickness of the confinement layer 60 is 100 nm.

The chip structure also includes an insulation layer 70, which is formed on a side surface of an epitaxial structure composed of the buffer layer 20, the N-type layer 30, the active layer 40, the P-type EBL layer (electron blocking layer) 51, and the confinement layer 60 and on an upper surface (a surface facing away from the substrate 10) of the confinement layer 60. A first electrode 81 is disposed on a lower surface (a surface facing away from the buffer layer 20) of the substrate 10, and overlaps with an orthographic projection of the mesa structure in the thickness direction. The second electrode 82 is disposed on an upper surface of the P-type cap layer 52.

### Fifth Embodiment

As shown in FIG. 1, a chip structure in the fifth embodiment includes, in sequence from bottom to top, a substrate 10, a buffer layer 20, an N-type layer 30, an active layer 40, a P-type EBL layer (electron blocking layer) 51, and a P-type cap layer 52. The P-type cap layer 52 is partially etched in a thickness direction to form a mesa structure. A confinement layer 60 is disposed on a side surface of the mesa structure (in an etched region of the P-type cap layer 52).

A material of the P-type EBL layer 51 is P-type AlGaN. A doping concentration of the P-type EBL layer 51 is 1E20. A thickness of the P-type EBL layer 51 is 50 nm.

A material of the P-type cap layer 52 is P-type GaN. A doping concentration of the P-type cap layer 52 is 6E19. A thickness of the P-type cap layer 52 is 200 nm. A height of the mesa structure is 170 nm, and a width of the mesa structure is 15 μm.

A material of the confinement layer 60 is GaN. A doping type is P-type. A doping concentration of the confinement layer 60 is 1E19. A thickness of the confinement layer 60 is 170 nm.

The chip structure also includes an insulation layer 70, which is formed on a side surface of an epitaxial structure composed of the buffer layer 20, the N-type layer 30, the active layer 40, the P-type EBL layer (electron blocking layer) 51 and on an upper surface (a surface facing away from the substrate 10) of the confinement layer 60. A first electrode 81 is disposed on a lower surface (a surface facing away from the buffer layer 20) of the substrate 10, and overlaps with an orthographic projection of the mesa structure in the thickness direction. The second electrode 82 is disposed on an upper surface of the P-type cap layer 52.

### Sixth Embodiment

As shown in FIG. 2, a chip structure in the sixth embodiment includes, in sequence from bottom to top, a substrate 10, a buffer layer 20, an N-type layer 30, an active layer 40, a P-type EBL layer (electron blocking layer) 51, and a P-type cap layer 52. The P-type cap layer 52 is completely etched in a thickness direction to form a mesa structure. A confinement layer 60 is disposed on a side surface of the mesa structure (in an etched region of the P-type cap layer 52).

A material of the P-type EBL layer 51 is P-type AlGaN. A doping concentration of the P-type EBL layer 51 is 1E20. A thickness of the P-type EBL layer 51 is 50 nm.

A material of the P-type cap layer 52 is P-type GaN. A doping concentration of the P-type cap layer 52 is 6E19. A thickness of the P-type cap layer 52 is 200 nm. A height of the mesa structure is 200 nm, and a width of the mesa structure is 15 μm.

A material of the confinement layer 60 is GaN. A doping type of the confinement layer 60 is P-type. A doping concentration of the confinement layer 60 is 1E19. A thickness of the confinement layer 60 is 200 nm.

The chip structure also includes an insulation layer 70, which is formed on a side surface of an epitaxial structure composed of the buffer layer 20, the N-type layer 30, the active layer 40, the P-type EBL layer (electron blocking layer) 51, and the confinement layer 60 and on an upper surface (a surface facing away from the substrate 10) of the confinement layer 60. A first electrode 81 is disposed on a lower surface (a surface facing away from the buffer layer 20) of the substrate 10, and overlaps with an orthographic projection of the mesa structure in the thickness direction. The second electrode 82 is disposed on an upper surface of the P-type cap layer 52.

### Seventh Embodiment

As shown in FIG. 1, a chip structure in the seventh embodiment includes, in sequence from bottom to top, a substrate 10, a buffer layer 20, an N-type layer 30, an active layer 40, a P-type EBL layer (electron blocking layer) 51, and a P-type cap layer 52. The P-type cap layer 52 is partially etched in a thickness direction to form a mesa structure. A confinement layer 60 is disposed on a side surface of the mesa structure (in an etched region of the P-type cap layer 52).

A material of the P-type EBL layer 51 is P-type AlGaN. A doping concentration of the P-type EBL layer 51 is 1E20. A thickness of the P-type EBL layer 51 is 50 nm.

A material of the P-type cap layer 52 is P-type GaN. A doping concentration of the P-type cap layer 52 is 1E20. A thickness of the P-type cap layer 52 is 300 nm. A height of the mesa structure is 250 nm, and a width of the mesa structure is 20 μm.

A material of the confinement layer 60 is GaN. A doping type of the confinement layer 60 is P-type. A doping concentration of the confinement layer 60 is 5E19. A thickness of the confinement layer 60 is 250 nm.

The chip structure also includes an insulation layer 70, which is formed on a side surface of an epitaxial structure composed of the buffer layer 20, the N-type layer 30, the active layer 40, the P-type EBL layer (electron blocking layer) 51, and the confinement layer 60 and on an upper surface (a surface facing away from the substrate 10) of the confinement layer 60. A first electrode 81 is disposed on a lower surface (a surface facing away from the buffer layer 20) of the substrate 10, and overlaps with an orthographic projection of the mesa structure in the thickness direction. The second electrode 82 is disposed on an upper surface of the P-type cap layer 52.

### Eighth Embodiment

As shown in FIG. 2, a chip structure in the eighth embodiment includes, in sequence from bottom to top, a substrate 10, a buffer layer 20, an N-type layer 30, an active layer 40, a P-type EBL layer (electron blocking layer) 51, and a P-type cap layer 52. The P-type cap layer 52 is completely etched along a thickness direction to form a mesa structure. A confinement layer 60 is disposed on a side surface of the mesa structure (in an etched region of the P-type cap layer 52).

A material of the P-type EBL layer 51 is P-type AlGaN. A doping concentration of the P-type EBL layer 51 is 1E20. A thickness of the P-type EBL layer 51 is 50 nm.

A material of the P-type cap layer 52 is P-type GaN. A doping concentration of the P-type cap layer 52 is 1E20. A thickness of the P-type cap layer 52 is 300 nm. A height of the mesa structure is 300 nm, and a width of the mesa structure is 20 μm.

A material of the confinement layer 60 is GaN. A doping type is P-type. A doping concentration of the confinement layer 60 is 5E19. A thickness of the confinement layer 60 is 300 nm.

The chip structure also includes an insulation layer 70, which is formed on a side surface of an epitaxial structure composed of the buffer layer 20, the N-type layer 30, the active layer 40, the P-type EBL layer (electron blocking layer) 51, and the confinement layer 60, and on an upper surface of the confinement layer 60. A first electrode 81 is disposed on a lower surface (a surface facing away from the buffer layer 20) of the substrate 10, and overlaps with an orthographic projection of the mesa structure in the thickness direction. The second electrode 82 is disposed on an upper surface of the P-type cap layer 52.

### Ninth Embodiment

As shown in FIG. 1, a chip structure in the ninth embodiment includes, in sequence from bottom to top, a substrate 10, a buffer layer 20, an N-type layer 30, an active layer 40, a P-type EBL layer (electron blocking layer) 51, and a P-type cap layer 52. The P-type cap layer 52 is partially etched in a thickness direction to form a mesa structure. A confinement layer 60 is disposed on a side surface of the mesa structure (in the etched region of the P-type cap layer 52).

A material of the P-type EBL layer 51 is P-type AlGaN. A doping concentration of the P-type EBL layer 51 is 1E18. A thickness of the P-type EBL layer 51 is 50 nm.

A material of the P-type cap layer 52 is P-type GaN. A doping concentration of the P-type cap layer 52 is 3E19. A thickness of the P-type cap layer 52 is 100 nm. A height of the mesa structure is 80 nm, and a width of the mesa structure is 8 μm.

A material of the confinement layer 60 is GaN. A doping type is N-type. A doping concentration of the confinement layer 60 is 5E19. A thickness of the confinement layer 60 is 80 nm.

The chip structure also includes an insulation layer 70, which is formed on a side surface of an epitaxial structure composed of the buffer layer 20, the N-type layer 30, the active layer 40, the P-type EBL layer (electron blocking layer) 51, and the confinement layer 60 and on an upper surface (a surface facing away from the substrate 10) of the confinement layer 60. A first electrode 81 is disposed on a lower surface (a surface facing away from the buffer layer 20) of the substrate 10, and overlaps with an orthographic projection of the mesa structure in the thickness direction. The second electrode 82 is disposed on an upper surface of the P-type cap layer 52.

### Tenth Embodiment

As shown in FIG. 2, a chip structure in the tenth embodiment includes, in sequence from bottom to top, a substrate 10, a buffer layer 20, an N-type layer 30, an active layer 40, a P-type EBL layer (electron blocking layer) 51, and the P-type cap layer 52. The P-type cap layer 52 is completely etched in a thickness direction to form a mesa structure. A confinement layer 60 is disposed on a side surface of the mesa structure (in an etched region of the P-type cap layer 52).

A material of the P-type EBL layer 51 is P-type AlGaN. A doping concentration of the P-type EBL layer 51 is 1E18. A thickness of the P-type EBL layer 51 is 50 nm.

A material of the P-type cap layer 52 is P-type GaN. A doping concentration of the P-type cap layer 52 is 6E19. A thickness of the P-type cap layer 52 is 100 nm. A height of the mesa structure is 100 nm, and a width of the mesa structure is 8 μm.

A material of the confinement layer 60 is GaN. The confinement layer 60 has no doping type. A thickness of the confinement layer 60 is 100 nm.

The chip structure also includes an insulation layer 70, which is formed on a side surface of an epitaxial structure composed of the buffer layer 20, the N-type layer 30, the active layer 40, the P-type EBL layer (electron blocking layer) 51, and the confinement layer 60 and on an upper surface (a surface facing away from the substrate 10) of the confinement layer 60. A first electrode 81 is disposed on a lower surface (a surface facing away from the buffer layer 20) of the substrate 10, and overlaps with an orthographic projection of the mesa structure in the thickness direction. The second electrode 82 is disposed on an upper surface of the P-type cap layer 52.

### Eleventh Embodiment

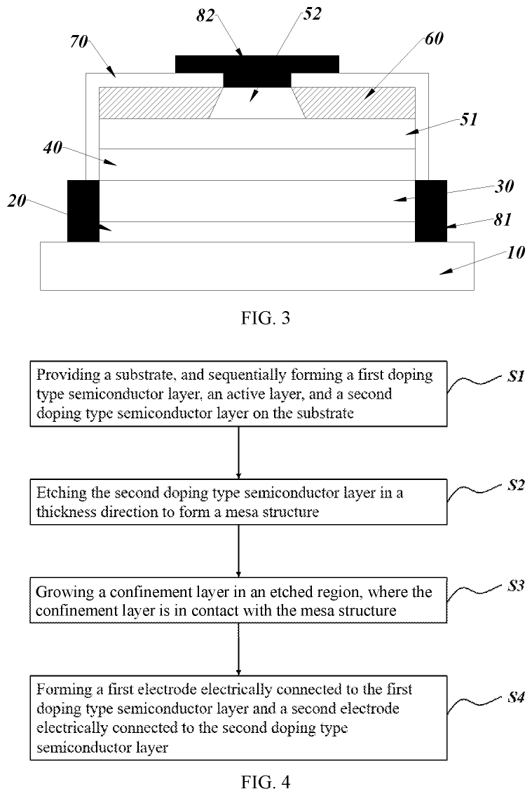

As shown in FIG. 3, a chip structure in the eleventh embodiment includes, in sequence from bottom to top, a substrate 10, a buffer layer 20, an N-type layer 30, an active layer 40, a P-type EBL layer (electron blocking layer) 51, and a P-type cap layer 52. The P-type cap layer 52 is completely etched along a thickness direction to form a mesa structure. A confinement layer 60 is disposed on a side surface of the mesa structure (in an etched region of the P-type cap layer 52).

A material of the P-type EBL layer 51 is P-type AlGaN. A doping concentration of the P-type EBL layer 51 is 1E19. A thickness of the P-type EBL layer 51 is 50 nm.

A material of the P-type cap layer 52 is P-type GaN. A doping concentration of the P-type cap layer 52 is 3E19. A thickness of the P-type cap layer 52 is 100 nm. A height of the mesa structure is 100 nm, and a width of the mesa structure is 8 μm.

A material of the confinement layer 60 is GaN. A doping type is P-type. A doping concentration of the confinement layer 60 is 1E18. A thickness of the confinement layer 60 is 100 nm.

The chip structure also includes an insulation layer 70, which is formed on a side surface of an epitaxial structure composed of the active layer 40, the P-type EBL layer (electron blocking layer) 51, and the confinement layer 60 and on an upper surface (a surface facing away from the substrate 10) of the confinement layer 60. A first electrode 81 is disposed on an upper surface (a surface close to the buffer layer 20) of the substrate 10 and is attached to side surfaces of the n-type layer 30 and the buffer layer 20. The second electrode 82 is disposed on an upper surface of the P-type cap layer 52.

### Twelfth Embodiment

As shown in FIG. 1, a chip structure in the twelfth embodiment includes, in sequence from bottom to top, a substrate 10, a buffer layer 20, an N-type layer 30, an active layer 40, a P-type EBL layer (electron blocking layer) 51, and a P-type cap layer 52. The P-type cap layer 52 is partially etched in a thickness direction to form a mesa structure. A confinement layer 60 is disposed on a side surface of the mesa structure (in an etched region of the P-type cap layer 52).

A material of the P-type EBL layer 51 is P-type AlGaN. A doping concentration of the P-type EBL layer 51 is 1E18. A thickness of the P-type EBL layer 51 is 50 nm.

A material of the P-type cap layer 52 is P-type GaAs, GaNAs, InGaN, or AlGaN. A doping concentration of the P-type cap layer 52 is 1E 19. A thickness of the P-type cap layer 52 is 50 nm. A height of the mesa structure is 30 nm, and a width of the mesa structure is 3 μm.

A material of the confinement layer 60 is GaAs, GaNAs, InGaN, or AlGaN (with the aluminum content of 0.4%). A doping type of the confinement layer 60 is P-type. A doping concentration of the confinement layer 60 is 1E18. A thickness of the confinement layer 60 is 30 nm.

The chip structure also includes an insulation layer 70, which is formed on a side surface of an epitaxial structure composed of the buffer layer 20, the N-type layer 30, the active layer 40, the P-type EBL layer (electron blocking layer) 51, and the confinement layer 60, and on an upper surface (a surface facing away from the substrate 10) of the confinement layer 60. A first electrode 81 is disposed on a lower surface (a surface facing away from the buffer layer 20) of the substrate 10, and overlaps with an orthographic projection of the mesa structure in the thickness direction. The second electrode 82 is disposed on an upper surface of the P-type cap layer 52.

Referring to FIG. 4, an embodiment of the present disclosure also provides a method for preparing the chip structure described above, and specifically, the method includes the following steps:
S1, providing a substrate and sequentially forming a first doping type semiconductor layer, an active layer, and a second doping type semiconductor layer on the substrate.

Exemplarily, a buffer layer, an N-type layer, an active layer, a P-type EBL layer, and a P-type cap layer are sequentially epitaxially grown on a surface of the substrate. A material of the P-type EBL layer may be P-type AlGaN. A material of the P-type cap layer may be P-type GaN.
S2, etching the second doping type semiconductor layer in a thickness direction to form a mesa structure.

Exemplarily, photolithography and development techniques may be employed to form a mask layer on a surface of the P-type cap layer. The material of the mask layer may be SiNx, SiO₂, etc. The P-type cap layer is etched to form the mesa structure using the mask layer.
S3, growing the confinement layer in an etched region, where the confinement layer is in contact with the mesa structure. The confinement layer has a second doping type, a first doping type, or no doping type. In a case that the confinement layer has the second doping type, a doping concentration of the confinement layer is less than a doping concentration of the second doping type semiconductor layer.

Exemplarily, the confinement layer is epitaxially grown with a low P-type dopant, no dopant, or an N-type dopant. The doping concentration of the confinement layer with the low P-type dopant is lower than a doping concentration of the P-type cap layer or the P-type EBL layer as far as possible. When the confinement layer is in direct contact with the P-type cap layer and the P-type EBL layer, the doping concentration of the confinement layer is lower than that of the lower doping concentration in the P-type cap layer and the P-type EBL layer. When the confinement layer is merely in direct contact with the P-type cap layer, the doping concentration of the confinement layer is lower than the doping concentration of the P-type cap layer.
S4, forming a first electrode electrically connected to the first doping type semiconductor layer and a second electrode electrically connected to the second doping type semiconductor layer.

Exemplarily, the first electrode is formed on a lower surface (a surface facing away from the buffer layer) of a substrate within a positive projection range of the mesa structure in the thickness direction. The second electrode is formed on an upper surface of the P-type cap layer. The second electrode is electrically isolated from the whole epitaxial structure via an insulation layer.

For another example, the first electrode is formed on an upper surface (a surface close to the buffer layer) of the substrate and is attached to side surfaces of the N-type layer and the buffer layer. The second electrode is formed on the upper surface of the P-type cap layer. The second electrode is electrically isolated from the whole epitaxial structure via the insulation layer.

Compared to the prior art, in the chip structure and the preparation method thereof provided in the embodiments of the present disclosure, by forming the confinement layer with a different doping type or a different concentration from that of the second doping type semiconductor layer in the etched region of the second doping type semiconductor layer, a space charge region is formed between the confinement layer and the etched sidewalls, so as to control a current flow path to allow the current bypass the etched sidewalls, thereby reducing a non-radiative recombination center and leakage current introduced by the etching damage, while also avoiding introducing other problems that adversely affect the device performance.

In the chip structure and the preparation method thereof provided in the embodiments of the present disclosure, by controlling the concentration difference between the confinement layer and the second doping type semiconductor layer and a proportion of the confinement layer relative to the thickness of the second doping type semiconductor layer, a size of the space charge region formed between the confinement layer and the second doping type semiconductor layer is controlled, and thus the current-limiting effect of the space charge region is further improved, thereby avoiding phenomena of the non-radiative recombination center and the leakage current of the etched sidewalls.

For those skilled in the art, the present disclosure is obviously not limited to details in the foregoing exemplary embodiments, and the present disclosure can be implemented in other specific forms without departing from the spirit or basic features of the present disclosure. Therefore, the embodiments should be considered to be exemplary and non-limiting in all respects. The scope of the disclosure is defined by the appended claims rather than the foregoing description. Therefore, all variations falling within the meaning and scope of the equivalent elements of the claims are intended to be included in the present disclosure. Any reference numerals in the claims should not be considered as a limitation on related claims.

In addition, it should be understood that, although the specification is described in terms of embodiments, not every embodiment merely includes an independent technical solution. This description of the specification is merely for the sake of clarity. Those skilled in the art should consider the specification as a whole, and the technical solution in each embodiment may also be combined as appropriate to form other embodiments that can be understood by those skilled in the art.

1. A Micro-LED vertical chip structure, comprising:
an epitaxial structure, the epitaxial structure comprising a first doping type semiconductor layer, a second doping type semiconductor layer, and an active layer disposed between the first doping type semiconductor layer and the second doping type semiconductor layer, wherein a mesa structure is formed by etching on a side of the second doping type semiconductor layer facing away from the active layer and is located in the middle of the second doping type semiconductor layer, wherein the epitaxial structure further comprises a confinement layer, the confinement layer is formed on the periphery of the mesa structure by epitaxial growth and is in contact with the mesa structure, and the confinement layer has a second doping type, a first doping type, or no doping type; and
a second electrode electrically connected to the second doping type semiconductor layer, wherein the second electrode is formed on a surface of the mesa structure;
wherein the Micro-LED vertical chip structure further comprises an insulation layer formed at least on a surface of the confinement laver facing away from the active layer and extending from the surface along a side surface of the confinement layer to a side surface of the active layer, and the second electrode is electrically isolated from the confinement laver via the insulation layer,
wherein a material of the confinement layer is a semiconductor material composed of any one of Group III elements Ga, In, and Al, and any one of Group V elements N, As, and P, wherein a space charge region is formed between the confinement layer and the second doping type semiconductor layer, and the space charge region controls a current flow path to allow current to bypass the side surface of the mesa structure, and
wherein in a case that the confinement layer has the second doping type, a doping concentration of the confinement layer is less than a doping concentration of the second doping type semiconductor layer in contact with the confinement layer, and in a case that the confinement layer contains Al, the Al content is less than 0.5%.

2. The Micro-LED vertical chip structure of claim 1, wherein
the second doping type semiconductor layer comprises a second doping type electron blocking layer formed on a surface of the active layer and a second doping type cap layer formed on a surface of the second doping type electron blocking layer,
a doping concentration of the second doping type electron blocking layer is 1E18 to 1E20, and
a doping concentration of the second doping type cap layer is 1E19 to 1E21.

3. The Micro-LED vertical chip structure of claim 2, wherein
the mesa structure is formed by partially etching the second doping type cap layer in a thickness direction; and
in the case that the confinement layer has the second doping type, the doping concentration of the confinement layer is less than the doping concentration of the second doping type cap layer.

4. The Micro-LED vertical chip structure of claim 3, wherein
a height of the mesa structure is less than a thickness of the second doping type cap layer, and
the height of the mesa structure is greater than half the thickness of the second doping type cap layer.

5. The Micro-LED vertical chip structure of claim 2, wherein
the mesa structure is formed by completely etching the second doping type cap layer in a thickness direction,
a height of the mesa structure is equal to a thickness of the second doping type cap layer, and
in the case that the confinement layer has the second doping type, the doping concentration of the confinement layer is less than the doping concentration of the second doping type cap layer and less than the doping concentration of the second doping type electron blocking layer.

6. The Micro-LED vertical chip structure of claim 3, wherein
the confinement layer is formed in an etched region, and a thickness of the confinement layer is equal to the height of the mesa structure.

7. The Micro-LED vertical chip structure of claim 1, wherein
in a case that the confinement layer has the first doping type, the doping concentration of the confinement layer ranges from 1E17 to 5E19, and
in the case that the confinement layer has the second doping type, the doping concentration confinement layer ranges from 1E17 to 1E20.

8. The Micro-LED vertical chip structure of claim 1, further comprising:
a first electrode electrically connected to the first doping type semiconductor layer.

9. (canceled)

10. The Micro-LED vertical chip structure of claim 8, wherein
the first electrode is formed on a surface of the first doping type semiconductor layer facing away from the active layer, and an orthographic projection of the first electrode in a thickness direction overlaps with an orthographic projection of the mesa structure in the thickness direction; or
the first electrode is formed on a side surface of the first doping type semiconductor layer.

11. A method for preparing the Micro-LED vertical chip structure of claim 1, comprising:
providing a substrate, and sequentially forming a first doping type semiconductor layer, an active layer, and a second doping type semiconductor layer on the substrate;
etching the second doping type semiconductor layer in a thickness direction to form a mesa structure;
growing a confinement layer in an etched region, wherein the confinement layer is in contact with the mesa structure, a material of the confinement layer is a semiconductor material composed of any one of group III elements Ga, In, and Al and any one of group V elements N, As, and P, the confinement layer has a second doping type, a first doping type, or no doping type, and in a case that the confinement layer has the second doping type, a doping concentration of the confinement layer is less than a doping concentration of the second doping type semiconductor layer in contact with the confinement layer; and
forming a first electrode electrically connected to the first doping type semiconductor layer and a second electrode electrically connected to the second doping type semiconductor layer.

12. The Micro-LED vertical chip structure of claim 4, wherein
the confinement layer is formed in an etched region, and a thickness of the confinement layer is equal to the height of the mesa structure.

13. The Micro-LED vertical chip structure of claim 5, wherein
the confinement layer is formed in an etched region, and a thickness of the confinement layer is equal to the height of the mesa structure.
